(19) United States
(12) Patent Application Publication
(10) Pub. No.: US 2025/0040191 A1
(43) Pub. Date: Jan. 30, 2025

(54) ENGINEERING METAL OXIDE LAYER INTERFACES TO IMPROVE ELECTRONIC DEVICE STABILITY

(71) Applicant: Applied Materials, Inc., Santa Clara, CA (US)

(72) Inventors: Dejiu Fan, Mountain View, CA (US); Yun-Chu Tsai, Taichung City (TW); Sheng-Wen Wang, Tainan City (TW); Dong Kil Yim, Pleasanton, CA (US); Soo Young Choi, Fremont, CA (US)

(21) Appl. No.: 18/776,441

(22) Filed: Jul. 18, 2024

Related U.S. Application Data
(60) Provisional application No. 63/528,688, filed on Jul. 25, 2023.

(51) Int. Cl. H01L 29/786; C23C 14/08; C23C 14/58; C23C 16/06; C23C 16/455; C23C 16/56; H01L 21/02; H01L 29/66

(52) U.S. Cl. CPC H01L 29/7869; C23C 14/08; C23C 14/5806; C23C 16/06; C23C 16/45523; C23C 16/56; H01L 21/02565; H01L 29/66969

(57) ABSTRACT

Embodiments described herein relate to engineering metal oxide layer interfaces to improve electronic device stability. For example, a transistor device can include a base structure and a metal oxide layer disposed on the base structure. The metal oxide layer includes at least one region having a gradient profile with respect to oxygen (O₂) composition.

### CROSS-REFERENCE TO RELATED APPLICATION(S)

The present application claims the benefit of U.S. Provisional Patent Application No. 63/528,688, filed on Jul. 25, 2023 and entitled “ENGINEERING METAL OXIDE LAYER INTERFACES TO IMPROVE ELECTRONIC DEVICE STABILITY”, the entire contents of which are hereby incorporated by reference herein.

### TECHNICAL FIELD

The present application generally relates to electronic device fabrication. More specifically, the present application relates to engineering metal oxide layer interfaces to improve electronic device stability.

### BACKGROUND

An electronic device manufacturing apparatus can include multiple chambers, such as process chambers and load lock chambers. Such an electronic device manufacturing apparatus can employ a robot apparatus in the transfer chamber that is configured to transport substrates or wafers between the multiple chambers. In some instances, multiple substrates are transferred together. Process chambers may be used in an electronic device manufacturing apparatus to perform one or more processes on substrates, such as deposition processes and etch processes.

Processes for fabrication of electronic devices (e.g., semiconductor devices) generally include deposition of material (e.g., one or more thin film layers) on a substrate, and processing of the material. Deposition chamber systems, such as chemical vapor deposition (CVD) chamber systems, utilize process gases to perform a deposition process to deposit the material onto a substrate. Examples of CVD deposition processes include plasma enhanced (PE) CVD, thermally enhanced (TE) CVD, high density plasma (HDP) CVD, etc. To perform such CVD deposition processes, a substrate or wafer can be placed within a reactor chamber, and chemical vapors can be introduced into the reactor chamber that cause deposition of a particular material.

### SUMMARY

In accordance with an embodiment, a transistor device is provided. The transistor device includes a base structure and a metal oxide layer disposed on the base structure. The metal oxide layer includes at least one region having a gradient profile with respect to oxygen (O₂) composition.

In accordance with another embodiment, a method is provided. The method includes obtaining a base structure of a transistor device, and forming, on the base structure using a gas mixture comprising oxygen (O₂), a metal oxide layer comprising at least one region having a gradient profile with respect to O₂ composition.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIGS. 1A-1F are diagrams of cross-sectional views illustrating an example process of fabricating an electronic device including engineering at least one metal oxide layer interface to improve electronic device stability, in accordance with some embodiments.

FIGS. 2A-2C are graphs illustrating oxygen gas (O₂) flow, plasma power and partial pressure of O₂ (pO₂) during the formation of a metal oxide layer using an example bottom interface engineering method for a metal oxide layer, in accordance with some embodiments.

FIGS. 3A-3C are graphs illustrating oxygen gas (O₂) flow, plasma power and partial pressure of O₂ (pO₂) during the formation of a metal oxide layer using an example bottom interface engineering method for a metal oxide layer, in accordance with some embodiments.

FIGS. 4A-4B are graphs illustrating oxygen gas (O₂) flow and partial pressure of O₂ (pO₂) during the formation of a metal oxide layer using an example bottom interface engineering method for a metal oxide layer, in accordance with some embodiments.

FIGS. 5A-5C are graphs illustrating oxygen gas (O₂) flow, plasma power and partial pressure of O₂ (pO₂) during the formation of a metal oxide layer using an example top interface engineering method for a metal oxide layer, in accordance with some embodiments.

FIGS. 6A-6C are graphs illustrating oxygen gas (O₂) flow, plasma power and partial pressure of O₂ (pO₂) during the formation of a metal oxide layer using an example top interface engineering method for a metal oxide layer, in accordance with some embodiments.

FIGS. 7A-7C are graphs illustrating partial pressure of O₂ (pO₂) during the formation of a metal oxide layer using an example top interface engineering method for a metal oxide layer, in accordance with some embodiments.

FIG. 8 is a graph illustrating oxygen gas (O₂) composition during the formation of a metal oxide layer using an example bottom interface engineering method and an example top interface engineering method, in accordance with some embodiments.

FIGS. 9-11B are flowcharts of example methods for fabricating electronic devices including engineering metal oxide layer interfaces to improve electronic device stability, in accordance with some embodiments.

### DETAILED DESCRIPTION

A transistor can be a component of an electronic device. In some implementations, a transistor is a component of a display device. In some implementations, a transistor is a component of a photovoltaic cell. For example, a transistor can be a component of a solar cell.

For example, a display device can be an organic light emitting diode (OLED) display device. An OLED display device can include a frontplane and a backplane. The frontplane is a layer including a number of pixels that generate images, and the backplane is a layer including switching circuitry having a number of components for controlling the pixels of the frontplane (e.g., an on/off state of the pixels). One example of a backplane is a low-temperature polycrystalline silicon (LTPS) backplane. An LTPS backplane utilizes LTPS to form the transistors of the switching circuitry included within the backplane (“LTPS transistors”). LTPS backplanes may not allow for dynamic changes in refresh rates absent external hardware. Another example of a backplane is a low-temperature polycrystalline oxide (LTPO) backplane. An LTPO backplane can include an LTPO device. The LTPO device can include switching circuitry to control a pixel of the frontplane, and driving circuitry to drive the display. The use of the driving circuitry can provide for a more efficient display that enables dynamic changes in refresh rates without using external hardware. The switching circuitry of an LTPO device can include an array of transistors.

In some implementations, a transistor is a field-effect transistor. For example, a transistor can include a substrate including one or more layers, a channel region disposed on the substrate and between a source region and a drain region, a gate structure disposed on the channel region. The channel region and the source/drain regions can be formed from a semiconductor layer, with the source/drain regions corresponding to respective doped regions of the semiconductor layer. In some implementations, the semiconductor layer is a metal oxide layer. The substrate can include one or more layers of materials. In some embodiments, the channel region and the source and drain regions are formed on a dielectric layer of the substrate. For example, the dielectric layer can be a buffer layer. The gate structure can include a gate dielectric disposed on the channel region, the source/drain regions and the substrate, and a gate conductor disposed on the gate dielectric. The transistor can further include an interlevel dielectric (ILD) layer disposed on the gate structure. The transistor can further include a set of contacts including a source contact electrically connected to the source region using a via, a drain contact electrically connected to the drain region using a via, and a gate contact electrically connected to the gate conductor using a via. The channel region becomes conductive when the transistor is turned on. A threshold voltage of the transistor is the minimum gate-to-source voltage that is sufficient to create a conducting path between the source region and the drain region. Output current (e.g., source-drain current) can be controlled by the voltage applied to the gate structure. More specifically, voltage applied to the gate conductor can generate an electric field that controls the flow of charge carriers through the channel region from the source region to the drain region. In some implementations, a transistor is a thin film transistor (TFT).

In some implementations, the channel region and the source and drain regions can be formed by forming a metal oxide layer on a substrate. For example, the metal oxide layer can be formed on a buffer layer of the substrate. The buffer layer can include any suitable dielectric material. Examples of dielectric materials that can be used to form buffer layers include silicon nitride (Si₃N₄), silicon dioxide (SiO₂), etc. For example, the channel region can be formed from a metal oxide layer, and the source region and the drain regions can be formed at respective ends of the region by doping respective regions of the metal oxide layer. The metal oxide layer can include any suitable metal oxide material. Examples of metal oxide materials include indium oxide, gallium oxide, zinc oxide, tin oxide, indium-zinc-oxide (IZO), indium-tin-oxide (ITO), indium-gallium oxide (IGO), gallium-zinc-oxide (GZO), gallium-tin-oxide (GTO), zinc-tin-oxide (ZTO), indium-gallium-zinc-oxide (IGZO), indium-gallium-tin-oxide (IGTO), indium-zinc-tin-oxide (IZTO), indium-gallium-zinc-tin-oxide (IGZTO), cadmium-tin-oxide (CTO), titanium-tin-oxide (TiTO), copper-aluminum-oxide (CAO), strontium-copper-oxide (SCO), etc.

The metal oxide layer can be formed on the substrate using a deposition process that uses a gas mixture including oxygen gas (O₂) and an inert gas. The inert gas can be a noble gas. One example of an inert gas that can be included in a gas mixture is argon (Ar). The presence and control of O₂ can impact the properties and characteristics of the metal oxide layer. For example, the level of the partial pressure of O₂ (pO₂), which is a measurement representing the pressure (e.g., concentration) of O₂ within the gas mixture, can be controlled during a deposition process. The total pressure of a gas mixture including O₂ and an inert gas is the sum of pO₂ and the partial pressure of the inert gas. For example, if the inert gas is Ar, then the partial pressure of Ar in the gas mixture can be represented by pAr. The pO₂ level within a gas mixture can be measured as a percent composition of O₂ relative to the composition of the inert gas (e.g., Ar). For example, for a gas mixture that includes an approximate 1:1 ratio of O₂ to the inert gas, the pO₂ level can be about 50%. The pO₂ level of a gas mixture can alter properties of the material being deposited. For example, a gas mixture with a higher pO₂ level can promote the formation of oxides, while a gas mixture with a lower pO₂ level can favor reduced or non-oxidized states.

Positive bias temperature stress (PBTS) of a transistor is a measure of voltage stress resulting from the application of a positive bias voltage to at least one contact of the transistor (e.g., gate contact, source contact and/or drain contact) at an elevated temperature (e.g., a temperature greater than a normal operating temperature of the transistor) over time. PBTS of a transistor can be used to assess the stability and/or reliability of electrical characteristics of the transistor over time by identifying any potential points of failure.

A metal oxide layer can include a first interfacial region and a second interfacial region separated by a non-interfacial region. More specifically, the first interfacial region can include a first metal oxide layer interface (“interface”) defined between a metal oxide layer and a substrate (e.g., a buffer layer), and the second interfacial region can include a second interface defined between the metal oxide layer and a gate dielectric of a gate structure. The non-interfacial region can be referred to as a bulk region. In some implementations the first interface is a bottom interface and the second interface is a top interface. A deposition process to form a metal oxide layer can employ a gas mixture of O₂ and an inert gas (e.g., Ar) that has a high pO₂ level, which can be used to reduce temperature sensitivity and to prevent transistor shorting. For example, a high pO₂ level can be an approximately constant or uniform at about 50% (i.e., 1:1 ratio between O₂ and the inert gas). However, using a high pO₂ level can degrade stability at one or more interfaces between a metal oxide layer and adjacent layers (e.g., the bottom interface between the metal oxide layer and the substrate and/or the top interface between the metal oxide layer and the gate dielectric), which can be reflected by large threshold voltage shift after PBTS (e.g., high PBTS). For example, the high PBTS can be caused at least in part by the generation of interface traps at the interface(s).

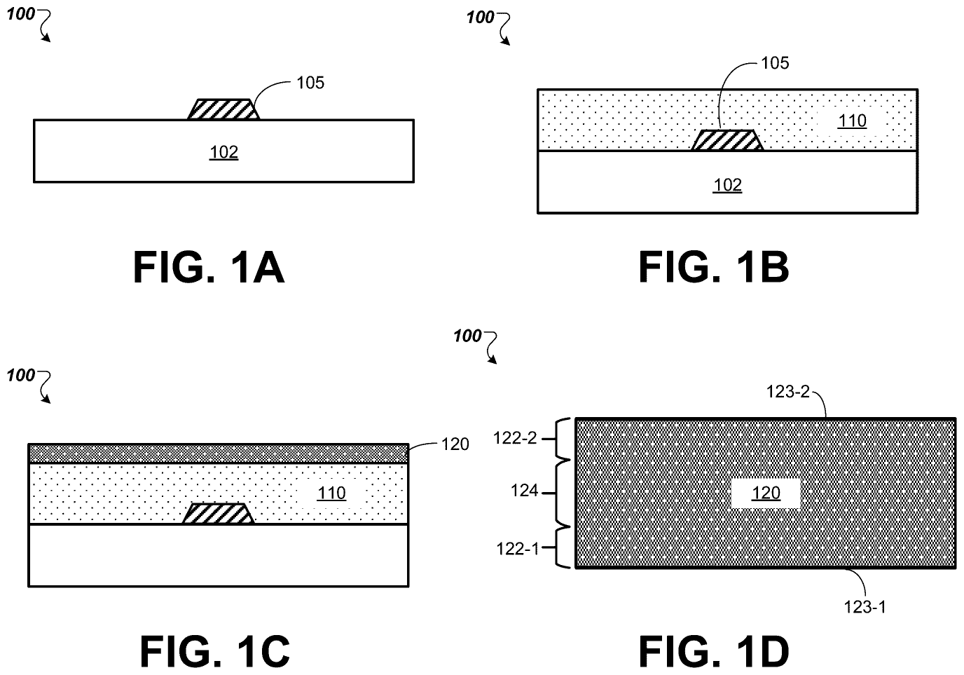

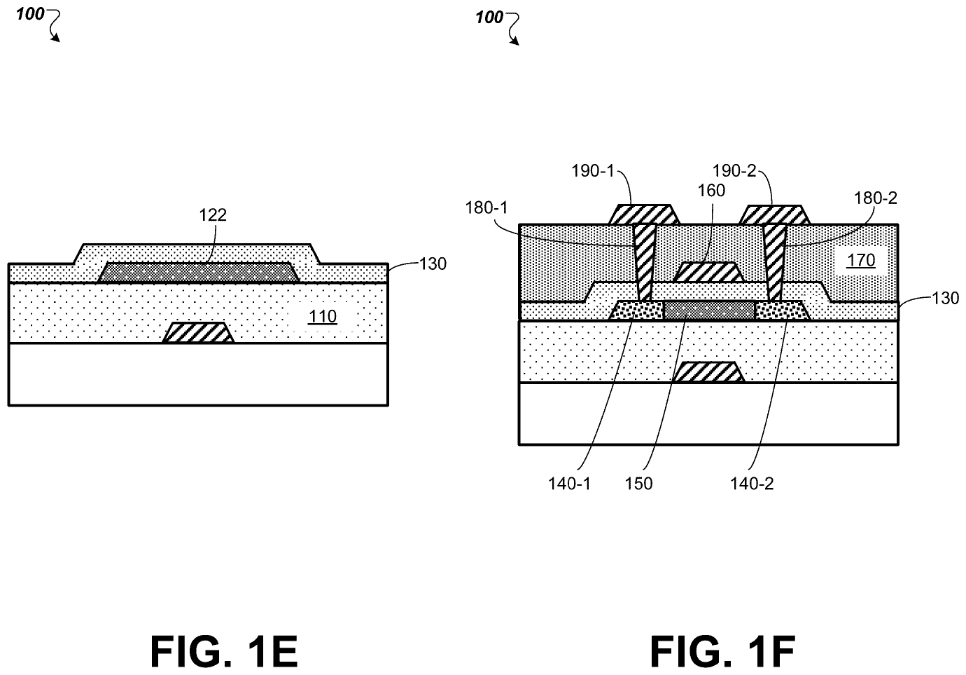

Aspects and implementations of the present disclosure address these and other shortcomings of existing technologies by engineering metal oxide layer interfaces to improve electronic device stability. For example, an electronic device can be a transistor device. Implementations described herein can employ at least one interface engineering method with respect to at least one interface. The at least one interface engineering method can be used to form at least one interfacial region of a metal oxide layer to reduce threshold voltage shift after PBTS while maintaining uniform high pO₂ in the bulk region. The at least one interface engineering method can include a bottom interface engineering method to reduce threshold voltage shift after PBTS with respect to a bottom interfacial region including a bottom interface and/or a top interface engineering method to reduce threshold voltage shift after PBTS with respect to interfacial region including a top interface. In some embodiments, one of the bottom interface engineering method or the top interface engineering method is performed. In some embodiment, both of the bottom interface engineering method and the top interface engineering method are performed. An interface engineering method described herein can be used to form an interfacial region having a gradient profile with respect to O₂ composition. For example, a bottom interface engineering method can be used to form a bottom interfacial region having a lowest O₂ composition at the bottom interface (e.g., the interface between the bottom interfacial region and the base structure), and a highest O₂ composition at the interface between the bottom interfacial region and the bulk region. As another example, a top interface engineering method can be used to form a top interfacial region having a lowest O₂ composition at the top interface (e.g., the interface between the top interfacial region and the gate dielectric), and a highest O₂ composition at the interface between the top interfacial region and the bulk region. Various embodiments for performing the bottom interface engineering method and/or the top interface engineering method are contemplated, as will be described in further detail below with reference to FIGS. 1A-9.

FIGS. 1A-1F are diagrams of cross-sectional views illustrating an example process of fabricating an electronic device (“device”) 100 to engineer at least one metal oxide layer interface to improve electronic device stability, in accordance with some embodiments. Device 100 is a transistor device in some embodiments. Alternatively, device 100 may be a different type of device.

FIG. 1A shows substrate 102 and gate conductor 105 formed on substrate 102. In some embodiments, gate conductor 105 is embedded within substrate 102. Substrate 102 can include one or more layers including an initial substrate layer. The initial substrate layer can be, for example, a silicon (Si) substrate layer, a glass substrate layer, a dielectric substrate layer (e.g., oxide layer), etc. In some embodiments, gate conductor 105 is a bottom gate conductor. Gate conductor 105 can include any suitable conductive material(s) in accordance with embodiments described herein. In some embodiments, gate conductor 105 includes a metal material. For example, gate conductor 105 can include at least one of copper (Cu), silver (Ag), gold (Au), aluminum (Al), zinc (Zn), nickel (Ni), titanium (Ti), molybdenum (Mo), etc.

FIG. 1B shows the formation of buffer layer 110 on substrate 102 and gate conductor 105. Buffer layer 110 can be formed from at least one dielectric material. Examples of dielectric materials that can be used to form the buffer layer include silicon nitride, silicon dioxide, etc. In some embodiments, buffer layer 110 is a single layer structure. In some embodiments, buffer layer 110 is a multi-layer structure. For example, buffer layer 110 can include at least two layers.

FIG. 1C shows the formation of metal oxide layer 120 on buffer layer 110. As will be described in further detail below with reference to FIGS. 1D-1F, metal oxide layer 120 can be used to form a channel region, a source region and a drain region of device 100. Metal oxide layer 120 can include any suitable metal oxide material. Examples of metal oxide materials include indium oxide, gallium oxide, zinc oxide, tin oxide, IZO, ITO, IGO, GZO, GTO, ZTO, IGZO, IGTO, IZTO, IGZTO, CTO, TITO, CAO, SCO, etc.

As shown in FIG. 1D, metal oxide layer 120 can include interfacial region 122-1 and interfacial region 122-2 separated by bulk region 124. Interfacial region 122-1 can include interface 123-1 and interfacial region 122-2 can include interface 123-2. Interface 123-1 corresponds to an interface between metal oxide layer 120 and base structure 110. Interface 123-2 corresponds to an interface between metal oxide layer 120 and a gate dielectric of a gate structure, as will be described in further detail below with reference to FIG. 1E. In some embodiments, interfacial region 122-1 is a bottom interfacial region, interface 123-1 is a bottom interface, interfacial region 122-2 is a top interfacial region, and interface 123-2 is a top interface.

Metal oxide layer 120 can be formed using a deposition process that utilizes a gas mixture including O₂ and an inert gas. In some embodiments, the inert gas is Ar. In some embodiments, the deposition process is a physical vapor deposition (PVD) process. For example, the deposition process can be a sputtering process. In some embodiments, the deposition process is a plasma-enhanced deposition process.

The deposition process used to form metal oxide layer 120 (e.g., PVD process) can implement at least one interface engineering method with respect to at least one of interfacial region 122-1 or interfacial region 122-2. More specifically, a first interface engineering method (e.g., a bottom interface engineering method) can be used to with respect to interfacial region 122-1 and/or a second interface engineering method (e.g., a top interface engineering method) can be used with respect to interfacial region 122-2.

In some embodiments, a first interface engineering method (e.g., bottom interface engineering method) includes initiating an inert gas flow of inert gas of a gas mixture, initiating, at a first time, formation of interfacial region 122-1 using a first O₂ flow of O₂ gas of the gas mixture, and ramping up, from the first time to a second time, the first O₂ flow to a second O₂ flow to form interfacial region 122-1. Bulk region 124 and interfacial region 122-2 can then be formed to complete the formation of metal oxide layer 120. More specifically, inert gas flow can be approximately constant or uniform, the first O₂ flow can be about 0, and the second O₂ flow can be selected to achieve a target pO₂ level of the gas mixture. For example, the second O₂ flow can be approximately equal to the inert gas flow, and the target pO₂ level can be about 50%. In some embodiments, the first time is 0 seconds(s). The difference between the first time and the second time defines an O₂ flow ramp up time. In some embodiments, the O₂ flow ramp up time ranges from about 0 s to about 90 s. In some embodiments, the O₂ flow ramp up time ranges from about 1 s to about 10 s. If the deposition process is a plasma-enhanced deposition process, then plasma power (“power”) can be ramped up to a target power while ramping up the O₂ flow to the target O₂ flow. For example, the target power can be ramped up to the target power at some time between t₀ and t₁, and the plasma power ramp up time can be less than the O₂ flow ramp up time.

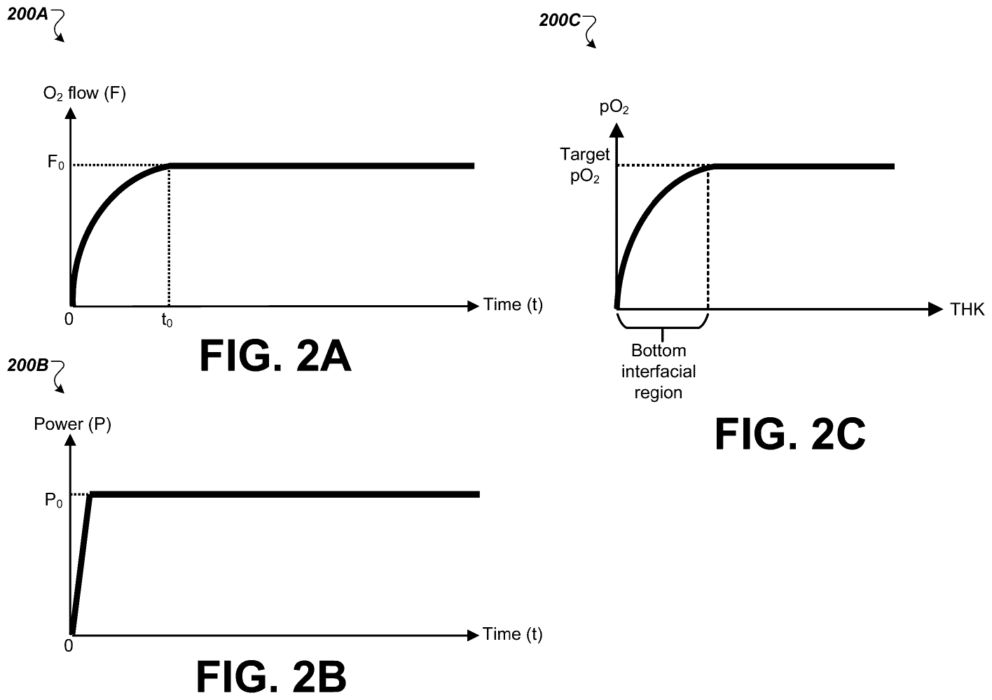

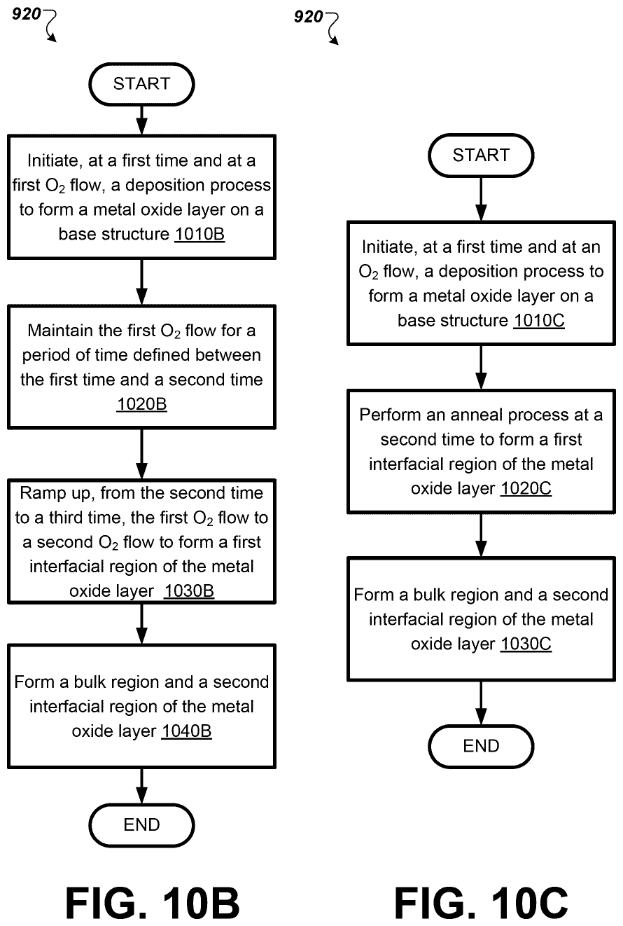

An illustrative example of O₂ flow (F) over time (t) is shown with reference to FIG. 2A, an illustrative example of plasma power (P) over time (t) is shown with reference to FIG. 2B, and an illustrative example of pO₂ (or O₂ composition) as a function of thickness (THK) of metal oxide layer 120 is shown with reference to FIG. 2C. In these examples, time 0 is the first time, time to is the second time, the first O₂ flow is about 0, F₀ is the second O₂ flow, P₀ is the target power, and Target pO₂ is the target pO₂ level. The thickness of metal oxide layer 120 is measured from interface 123-1 as a starting point. Thus, the total thickness of metal oxide layer 120 can be defined as the thickness between interface 123-1 and interface 123-2. Further details regarding these first interface engineering methods will be described below with reference to FIG. 10A.

Referring back to FIGS. 1C-1D, in some embodiments, a first interface engineering method (e.g., bottom interface engineering method) includes initiating an inert gas flow of an inert gas of a gas mixture, initiating, at a first time, formation of interfacial region 122-1 using a first O₂ flow of O₂ gas of the gas mixture, maintaining the first O₂ flow for a period of time defined between the first time and a second time, and ramping up, from the second time to a third time, the first O₂ flow to a second O₂ flow to form interfacial region 122-1. Bulk region 124 and interfacial region 122-2 can then be formed to complete the formation of metal oxide layer 120. More specifically, inert gas flow can be approximately constant or uniform, the first O₂ flow can be initiated at approximately the same time as the inert gas flow (e.g., sometime before the first time), the first O₂ flow can be selected to achieve a first target pO₂ level of the gas mixture, and the second O₂ flow can be selected to achieve a second target pO₂ level of the gas mixture. For example, the first O₂ flow can be less than the inert gas flow and the first target pO₂ level can be less than about 50%, and the second O₂ flow can be approximately equal to the inert gas flow and the second target pO₂ level can be about 50%. Thus, the first O₂ flow can be a “low O₂ flow” and the second O₂ flow can be a “high O₂ flow.” In some embodiments, the first time is 0 seconds(s). The difference between the second time and the third time defines an O₂ flow ramp up time. In some embodiments, the O₂ flow ramp up time ranges from about 0 s to about 90 s. In some embodiments, the O₂ flow ramp up time ranges from about 1 s to about 10 s. If the deposition process is a plasma-enhanced deposition process, then plasma power (“power”) can be ramped up to a target power while ramping up the O₂ flow from the first target O₂ flow to the second target O₂ flow. For example, the target power can be ramped up to the target power at some time between t₁ and t₂, and the plasma power ramp up time can be less than the O₂ flow ramp up time.

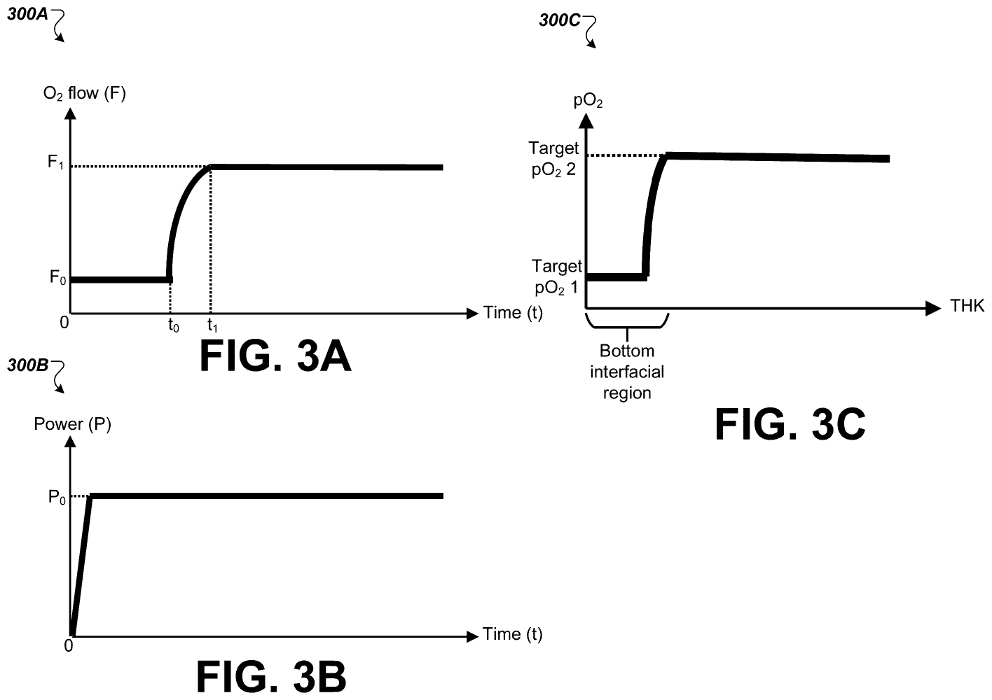

An illustrative example of O₂ flow (F) over time (t) is shown with reference to FIG. 3A, an illustrative example of plasma power (P) over time (t) is shown with reference to FIG. 3B, and an illustrative example of pO₂ (or O₂ composition) as a function of thickness (THK) of metal oxide layer 120 is shown with reference to FIG. 3C. In these examples, time 0 is the first time, time to is the second time, time t₁ is the third time, F₀ is the first O₂ flow, F₁ is the second O₂ flow P₀ is the target power, Target pO₂ 1 is the first target pO₂ level, and Target pO₂ 2 is the second target pO₂ level. The thickness of metal oxide layer 120 refers to the distance starting from interface 123-1 moving toward interface 123-2. Thus, the total thickness of metal oxide layer 120 can be defined as the thickness between interface 123-1 and interface 123-2. Further details regarding these first interface engineering methods will be described below with reference to FIG. 10B.

Referring back to FIGS. 1C-1D, in some embodiments, a first interface engineering method includes initiating an inert gas flow of an inert gas of a gas mixture, initiating, at a first time, formation of interfacial region 122-1 using an O₂ flow of O₂ gas of the gas mixture, and performing an anneal process at a second time to form interfacial region 122-1. Bulk region 124 and interfacial region 122-2 can then be formed to complete the formation of metal oxide layer 120. More specifically, the deposition process stops to perform the anneal process, and the resumes after the anneal process is complete. The second time corresponds to a target thickness of interfacial region 122-1. In some embodiments, the target thickness ranges from about 0 nanometers (nm) to about 20 nm. The anneal process can be performed at any suitable temperature. In some embodiments, the anneal process is performed at a temperature that ranges from about 200° C. to about 400° C. The anneal process reduces the pO₂ level of interfacial region 122-1 to a first target pO₂ level from a second target pO₂ level. For example, the second target pO₂ level can be about 50%.

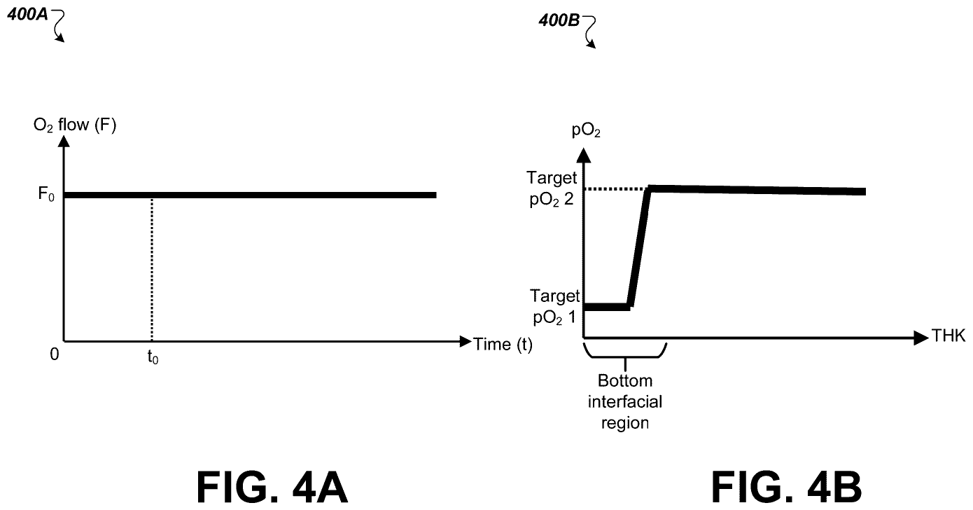

An illustrative example of O₂ flow (F) over time (t) is shown with reference to FIG. 4A, and an illustrative example of pO₂ (or O₂ composition) as a function of thickness (THK) of metal oxide layer 120 is shown with reference to FIG. 4B. In these examples, time 0 is the first time, time to is the second time, F₀ is the O₂ flow, P₀ is the target power, Target pO₂ 1 is the first target pO₂ level, and Target pO₂ 2 is the second target pO₂ level. The thickness of metal oxide layer 120 refers to the distance starting from interface 123-1 moving toward interface 123-2. Thus, the total thickness of metal oxide layer 120 can be defined as the thickness between interface 123-1 and interface 123-2. Further details regarding these first interface engineering methods will be described below with reference to FIG. 10C.

Referring back to FIGS. 1C-1D, in some embodiments, a second interface engineering method (e.g., top interface engineering method) includes forming a portion of a metal oxide layer including interfacial region 122-1 and bulk region 124 using a gas mixture having a first O₂ flow and an inert gas flow, and ramping down the O₂ flow from the first O₂ flow to a second O₂ flow to form interfacial region 122-2. More specifically, an inert gas flow can be approximately constant or uniform, and the first O₂ flow can be selected to achieve a target pO₂ level of the gas mixture. For example, the target O₂ flow can be approximately equal to the inert gas flow, and the target pO₂ level can be about 50%. In some embodiments, the second O₂ flow is approximately zero. The ramp down can be performed during an O₂ flow ramp down time defined as the difference between a first time after forming the portion of the metal oxide layer and a second time. In some embodiments, the O₂ flow ramp down time ranges from about 1 s to about 90 s. In some embodiments, the O₂ flow ramp down time ranges from about 2 s to about 10 s. If the deposition process is a plasma-enhanced deposition process, then plasma power (“power”) can be maintained at a target power while ramping down the O₂ flow to the second O₂ flow. For example, the target power can be ramped up to the target power during the formation of the portion of the metal oxide layer (e.g., during the formation of interfacial region 122-1).

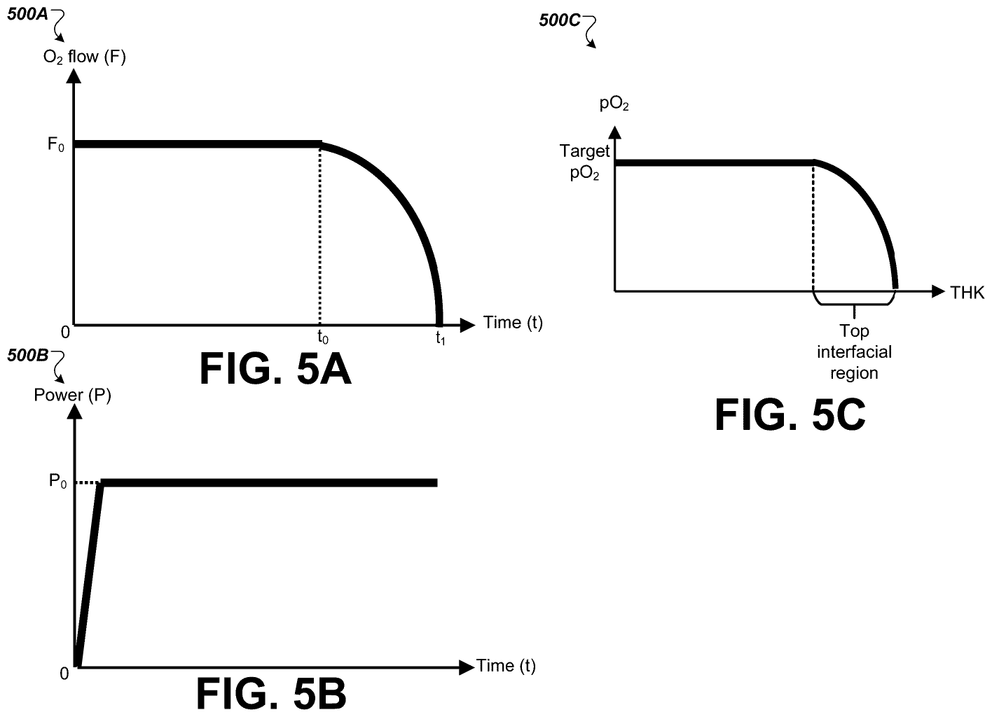

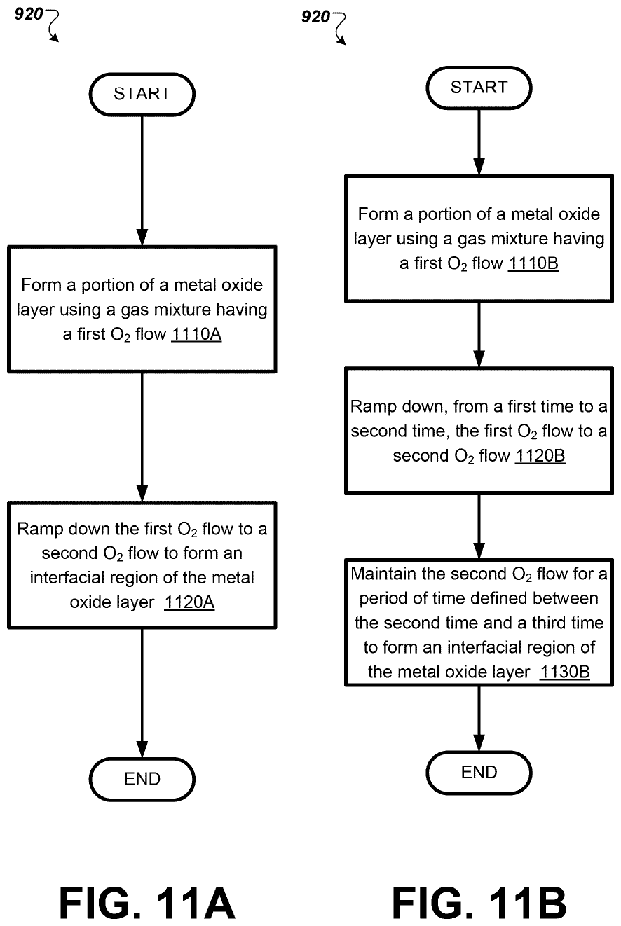

An illustrative example of O₂ flow (F) over time (t) is shown with reference to FIG. 5A, an illustrative example of plasma power (P) over time (t) is shown with reference to FIG. 5B, and an illustrative example of pO₂ (or O₂ composition) as a function of thickness (THK) of metal oxide layer 120 is shown with reference to FIG. 5C. In these examples, the portion of the metal oxide layer is formed from time 0 to the first time (to), time t₁ is the second time, F₀ is the first O₂ flow, the second O₂ flow is approximately 0, P₀ is the target power, and Target pO₂ is the target pO₂ level. Further details regarding these second interface engineering methods are described below with reference to FIG. 11A.

Referring back to FIGS. 1C-1D, in some embodiments, a second interface engineering method (e.g., top interface engineering method) includes forming a portion of a metal oxide layer including interfacial region 122-1 and bulk region 124 using a gas mixture having a first O₂ flow and an inert gas flow, ramping down, from a first time to a second time, the first O₂ flow to a second O₂ flow, and maintaining the second O₂ flow for a period of time defined between the second time and a third time to form interfacial region 122-2. More specifically, an inert gas flow can be approximately constant or uniform, the first O₂ flow can be selected to achieve a first target pO₂ level of the gas mixture, and the second O₂ flow can be selected to achieve a second target pO₂ level of the gas mixture. For example, the first O₂ flow can be approximately equal to the inert gas flow, and the first target pO₂ level can be about 50%. The difference between the first time and the second time defines an O₂ flow ramp down time. In some embodiments, the O₂ flow ramp down time ranges from about 0 s to about 90 s. In some embodiments, the O₂ flow ramp down time ranges from about 1 s to about 10 s. If the deposition process is a plasma-enhanced deposition process, then plasma power (“power”) can be maintained at a target power while ramping down the O₂ flow to the second O₂ flow. For example, the target power can be ramped up to the target power during the formation of the portion of the metal oxide layer (e.g., during the formation of interfacial region 122-1).

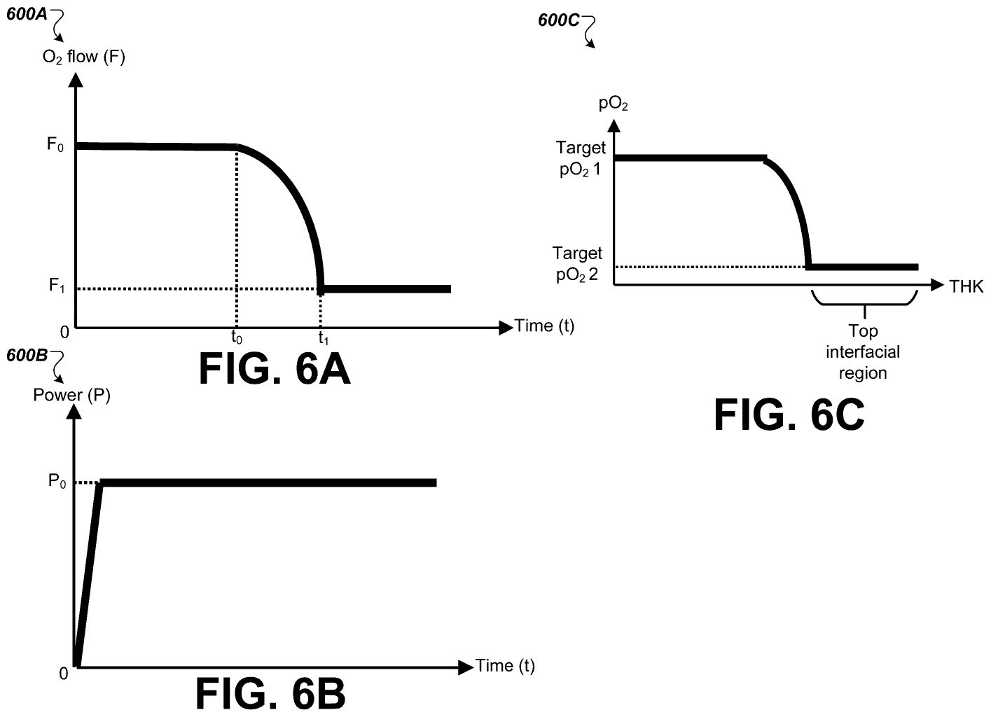

An illustrative example of O₂ flow (F) over time (t) is shown with reference to FIG. 6A, an illustrative example of plasma power (P) over time (t) is shown with reference to FIG. 6B, and an illustrative example of pO₂ (or O₂ composition) as a function of thickness (THK) of metal oxide layer 120 is shown with reference to FIG. 6C. In these examples, the portion of the metal oxide layer is formed from time 0 to the first time (to), time t₁ is the second time, F₀ is the first O₂ flow, F₁ is the second O₂ flow, P₀ is the target power, Target pO₂ 1 is the first target pO₂ level, and Target pO₂ 2 is the second target pO₂ level. Further details regarding these second interface engineering methods are described below with reference to FIG. 11B.

FIG. 1E shows the patterning of metal oxide layer 120 to form patterned metal oxide layer 122, and the formation of gate dielectric 130 on patterned metal oxide layer and buffer layer 110. Gate dielectric 130 can include any suitable material in accordance with embodiments described herein. In some embodiments, the gate dielectric 130 includes an oxide material. For example, gate dielectric 130 can include silicon dioxide (SiO₂).

In some embodiments, a second interface engineering method involves forming the gate dielectric using a deposition process performed at a target temperature to cause a target dissociation of O₂ at least from interfacial region 122-2. Dissociation of O₂ has the effect of decreasing pO₂ (or O₂ composition) of interfacial region 122-2. In some embodiments, a second interface engineering method (e.g., top interface engineering method) includes forming the gate dielectric on the metal oxide layer using a deposition process performed at a temperature that is greater than or equal to a threshold temperature. In some embodiments, the deposition process is a chemical vapor deposition (CVD) process. For example, the deposition process can be a plasma-enhanced CVD (PECVD) process. The higher the temperature, the greater the amount of dissociation of O₂ from interfacial region 122-2, and thus the greater the decrease in pO₂ (or O₂ composition). In some embodiments, the temperature ranges from about 200° C. to about 500° C.

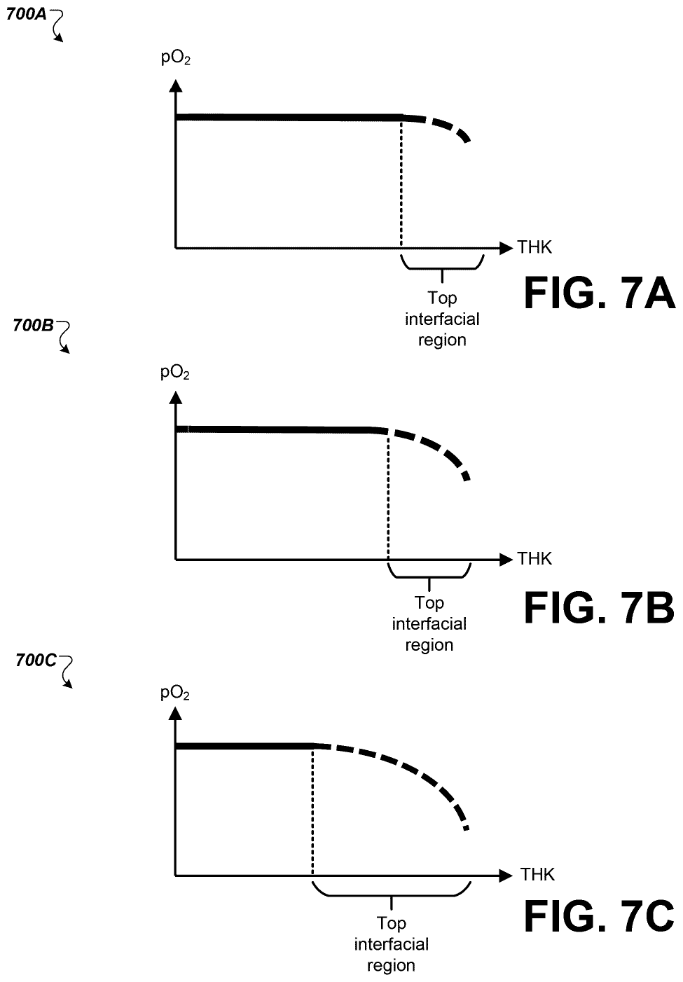

For example, FIG. 7A illustrates pO₂ as a function of thickness (THK) of metal oxide layer in which the gate dielectric is formed at a first temperature, FIG. 7B illustrates pO₂ as a function of thickness (THK) of metal oxide layer in which the gate dielectric is formed at a second temperature greater than the first temperature, and FIG. 7C illustrates pO₂ as a function of thickness (THK) of metal oxide layer in which the gate dielectric is formed at a third temperature greater than the second temperature.

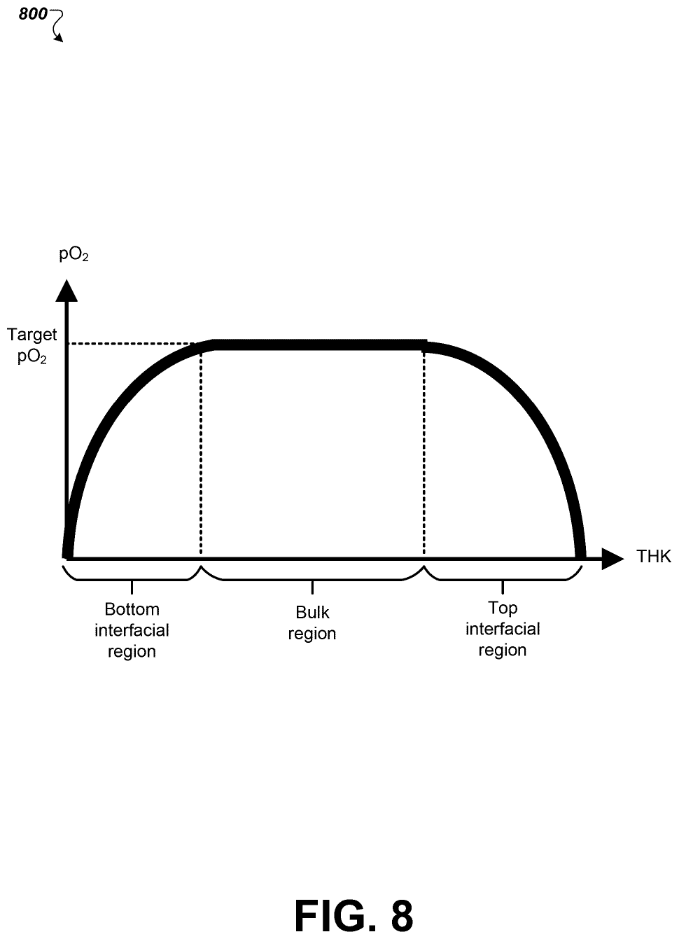

In some embodiments, both a first interface engineering method and a second interface engineering method are used with respect to interfacial regions 122-1 and 122-2, respectively. An illustrative example of pO₂ (or O₂ composition) as a function of thickness (THK) of metal oxide layer 120 is shown with reference to FIG. 8. As shown in FIG. 8, pO₂ increases from the bottom interface of bottom interfacial region to the end of the bottom interfacial region to achieve a target pO₂, pO₂ is maintained at approximately the target pO₂ throughout the bulk region, and pO₂ decreases from the beginning of the top interfacial region to the top interface of the top interfacial region.

FIG. 1F shows further processing to complete fabrication of device 100. For example, patterned metal oxide layer 120 can be processed to form source/drain region 140-1, drain/source region 140-2 and channel region 150. More specifically, a central segment of patterned metal oxide layer 122 defines channel region 150, and segments of patterned metal oxide layer 122 adjacent to the central segment can be processed to form source/drain region 140-1 and drain/source region 140-2. In some embodiments, forming source/drain regions 140-1 and 140-2 includes doping the segments of patterned metal oxide layer 122 adjacent to the central segment. Doping refers to a process of introducing dopants as impurities into an intrinsic semiconductor to obtain an extrinsic semiconductor. For example, openings can be created in gate dielectric 130 to expose the segments to perform the doping. Doping can be used to adjust the threshold voltage of the transistor device. In some embodiments, the semiconductor layer is doped with an n-type dopant to form an n-type semiconductor. An n-type semiconductor is an extrinsic semiconductor that is formed by doping an intrinsic semiconductor with electron donor atoms (e.g., the majority of charge carriers are electrons). In contrast, a p-type semiconductor is an extrinsic semiconductor that is formed by doping an intrinsic semiconductor with electron acceptor atoms (e.g., the majority of charge carriers are holes). For example, n+ doping can be performed, in which the “+” symbol denotes a high or heavy amount of doping (e.g., the number of dopant atoms added is on the order of one per ten thousand atoms). Doping the semiconductor material using an n+ doping process (e.g., ion implantation) can provide improvements with respect to hydrogen diffusion by, for example, increasing the diffusion path. In some embodiments, doping is performed using ion implantation. In some embodiments, doping is performed using a plasma treatment process.

As further shown in FIG. 1F, gate conductor 160 can be formed on gate dielectric 130. Forming gate conductor 160 can include depositing a conductive material, and etching the conductive material to form gate conductor 160. Gate conductor 160 can include any suitable conductive material(s) in accordance with embodiments described herein. In some embodiments, gate conductor 160 includes a metal material. For example, gate conductor 160 can include at least one of Cu, Ag, Au, Al, Zn, Ni, Ti, Mo, etc. Gate dielectric 130 and gate conductor 160 collectively form a gate structure.

As further shown in FIG. 1F, interlevel dielectric (ILD) layer 170 can be formed on the gate structure including gate dielectric 130 and gate conductor 160. ILD layer 170 can include any suitable dielectric material(s). Examples of suitable materials that can be used to form ILD layer 170 include silicon dioxide (SiO₂), silicon nitride, etc. In some embodiments, ILD layer 170 is a single layer. In some embodiments, ILD layer includes at least two layers.

As further shown in FIG. 1F, via 180-1 and via 180-2 can be formed in contact with source/drain region 140-1 and drain/source region 140-2, respectively, and source/drain contact 190-1 and drain/source contact 190-2 are formed on via 180-1 and 180-2, respectively. Accordingly, source/drain region 140-1 is electrically coupled to source/drain contact 190-1 and drain/source region 140-2 is electrically coupled to drain/source contact 190-2. Via 180-1, via 180-2, source/drain contact 190-1 and drain/source contact 190-2 can include any suitable conductive material(s) in accordance with embodiments described herein (e.g., metals). Examples of suitable conductive material(s) can include at least one of Cu, Ag, Au, Al, Zn, Ni, Ti, Mo, etc. Forming vias 180-1 and 180-2 can include forming a respective through holes through a respective number of layers to expose regions 140-1 and 140-2, and depositing a conductive material within the through holes. Forming contacts 190-1 and 190-2 can include depositing a conductive material, and etching the conductive material to form contacts 190-1 and 190-2 using an etch mask.

In this illustrative example, device 100 includes a transistor device having a planar transistor structure in which the source, drain and channel regions are arranged in a horizontal configuration. Alternatively, device 100 can include a transistor device having a fin field-effect transistor (FinFET) structure in which the gate structure is placed along multiple sides of the channel region (e.g., wrapped around the channel region). That is, a FinFET can be referred to as a multi-gate device. Alternatively, device 100 can include a vertical transistor device (e.g., vertical FET (VFET) or vertical transport FET (VTFET)) in which the source, drain and channel regions are arranged in a vertical configuration.

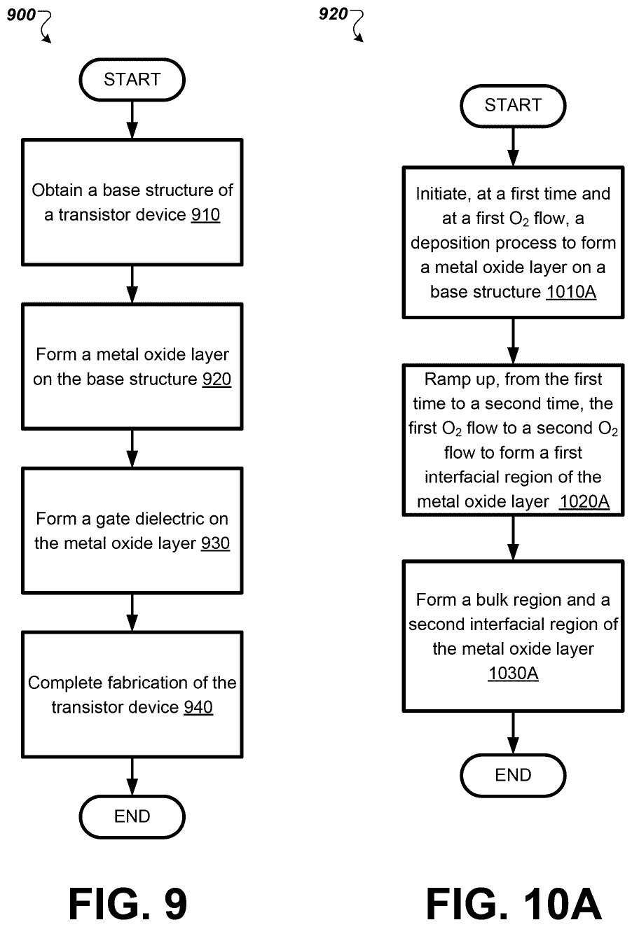

FIG. 9 depicts a flowchart of an example method 900 for fabricating an electronic device, in accordance with some embodiments. For example, method 900 can be used to fabricate device 100 described above with reference to FIGS. 1A-1F.

At block 910, a base structure of a transistor device is obtained. In some embodiments, the base structure includes a buffer layer.

At block 920, a metal oxide layer is formed on the base structure and, at block 930 a gate dielectric is formed on the metal oxide layer. For example the metal oxide layer can be formed on the buffer layer. The metal oxide layer can include a first interfacial region (e.g., bottom interfacial region) and a second interfacial region (e.g., top interfacial region) separated by a bulk region. The first interfacial region can include a first interface (e.g., bottom interface) defined between the metal oxide layer and the base structure (e.g., the buffer layer). The second interfacial region can include a second interface (e.g., bottom interface) defined between the metal oxide layer and the gate dielectric layer.

Forming the metal oxide layer can include performing a deposition process using a gas mixture including O₂ and an inert gas. In some embodiments, the deposition process is a PVD process. For example, the deposition process can be a sputtering process.

The metal oxide layer can include at least one region having a gradient profile with respect to O₂ composition. More specifically, at least one interface engineering method can be used to form at least one region of the metal oxide layer to have a gradient profile with respect to O₂ composition.

In some embodiments, the first interfacial region is formed using at least one first interface engineering method. In some embodiments, a first interface engineering method involves ramping up O₂ flow during a deposition process to form the metal oxide layer. In some embodiments, a first interface engineering method involves initiating a deposition process to form the metal oxide layer, stopping the deposition process, performing an anneal process after stopping the deposition process to form the first interfacial region, and resuming the deposition process after performing the anneal process. Further details regarding first interface engineering methods are described above with reference to FIGS. 1C-4B and will be described in further detail below with reference to FIGS. 10A-10C.

In some embodiments, the second interfacial region is formed using at least one second interface engineering method. In some embodiments, a second interface engineering method involves ramping down O₂ flow during a deposition process to form the metal oxide layer. Further details regarding these second interface engineering methods are described above with reference to FIGS. 1C and 5A-6C and will be described below with reference to FIGS. 11A-11B.

In some embodiments, a second interface engineering method involves forming the gate dielectric using a deposition process performed at a target temperature to cause a target dissociation of O₂ from the metal oxide layer. In some embodiments, the second interface engineering method includes forming the gate dielectric on the metal oxide layer using a deposition process performed at a temperature that is greater than or equal to a threshold temperature. The deposition process can be any suitable deposition process. In some embodiments, the deposition process is a CVD process. For example, the deposition process can be a PECVD process. Further details regarding these second interface engineering methods are described above with reference to FIGS. 1C and 7C.

The metal oxide layer can be formed using any suitable deposition process. For example, at least one interface engineering method can be used to form at least one interfacial region of the metal oxide layer prior to forming the gate dielectric at the target temperature. Multiple interface engineering methods can be used. For example, the first interfacial region and the second interfacial region can be formed using at least one first interface engineering method and at least one second interface engineering method (e.g., as shown in FIG. 8).

At block 940, fabrication of the transistor device is completed. For example, completing fabrication of the transistor device can include at least one of: forming a channel region and a pair of source/drain regions from the metal oxide layer, forming a gate conductor on the gate dielectric to form a gate structure, forming an ILD layer on the gate structure, or forming a set of contacts. For example, the set of contacts can include a pair of source/drain contacts electrically coupled to the pair of source/drain regions. As another example, the set of contacts can include a gate contact electrically coupled to the gate conductor. Further details regarding blocks 910-940 are described above with reference to FIGS. 1A-8 and will now be described below with reference to FIGS. 10A-11B.

FIG. 10A depicts a flowchart of an example method 920 for forming a metal oxide layer on a base structure of a transistor device, in accordance with some embodiments. More specifically, FIG. 10A shows an example first interface engineering method to form a first interfacial region (e.g., a bottom interfacial region) of the metal oxide layer.

At block 1010A, a deposition process to form a metal oxide layer on a base structure is initiated at a first time and a first O₂ flow.

At block 1020A, the first O₂ flow is ramped up, from the first time to a second time, to a second O₂ flow to form a first interfacial region of the metal oxide layer.

At block 1030A, a bulk region and a second interfacial region of the metal oxide layer are formed. Further details regarding blocks 1010A-1030A are described above with reference to FIGS. 1C and 2A-2C.

FIG. 10B depicts a flowchart of an example method 920 for forming a metal oxide layer on a base structure of a transistor device, in accordance with some embodiments. More specifically, FIG. 10B shows an example first interface engineering method to form a first interfacial region (e.g., a bottom interfacial region) of the metal oxide layer.

At block 1010B, a deposition process to form a metal oxide layer on a base structure is initiated at a first time and a first O₂ flow.

At block 1020B, the first O₂ flow is maintained for a period of time defined between the first time and a second time.

At block 1030B, the first O₂ flow is ramped up, from the second time to a third time, to a second O₂ flow.

At block 1040B, a bulk region and a second interfacial region of the metal oxide layer are formed. Further details regarding blocks 1010B-1040B are described above with reference to FIGS. 1C and 3A-3C.

FIG. 10C depicts a flowchart of an example method 920 for forming a metal oxide layer on a base structure of a transistor device, in accordance with some embodiments. More specifically, FIG. 10B shows an example first interface engineering method to form a first interfacial region (e.g., a bottom interfacial region) of the metal oxide layer.

At block 1010C, a deposition process to form a metal oxide layer on a base structure is initiated at a first time and a first O₂ flow.

At block 1020C, an anneal process is performed at a second time to form a first interfacial region of the metal oxide layer. More specifically, the deposition process can be stopped prior to performing the anneal process.

At block 1030C, a bulk region and a second interfacial region of the metal oxide layer are formed. More specifically, the deposition process can be resumed after performing the anneal process. Further details regarding blocks 1010C-1030C are described above with reference to FIGS. 1C and 4A-4B.

FIG. 11A depicts a flowchart of an example method 920 for forming a metal oxide layer on a base structure of a transistor device, in accordance with some embodiments. More specifically, FIG. 11A shows an example second interface engineering method to form a second interfacial region (e.g., a top interfacial region) of the metal oxide layer.

At block 1110A, a portion of a metal oxide layer is formed using a gas mixture having a first O₂ flow. More specifically, the portion of the metal oxide layer can include a first interfacial region including a first interface formed on a base structure (e.g., a buffer layer) and a bulk region.

At block 1120A, the first O₂ flow is ramped down to a second O₂ flow to form an interfacial region of the metal oxide layer. In some embodiments, the second O₂ flow is approximately zero. Further details regarding blocks 1110A-1120A are described above with reference to FIGS. 1C and 5A-5C.

FIG. 11B depicts a flowchart of an example method 920 for forming a metal oxide layer on a base structure of a transistor device, in accordance with some embodiments. More specifically, FIG. 11B shows an example second interface engineering method to form a second interfacial region (e.g., a top interfacial region) of the metal oxide layer.

At block 1110B, a portion of a metal oxide layer is formed using a gas mixture having a first O₂ flow. More specifically, the portion of the metal oxide layer can include a first interfacial region including a first interface formed on a base structure (e.g., a buffer layer) and a bulk region.

At block 1120B, the first O₂ flow is ramped down, from a first time to a second time, to a second O₂ flow. In some embodiments, the second O₂ flow is greater than zero and less than the first O₂ flow.

At block 1130B, the second O₂ flow is maintained for a period of time defined between the second time and a third time to form an interfacial region of the metal oxide layer. For example, the interfacial region can be a top interfacial region. Further details regarding blocks 1110B-1130B are described above with reference to FIGS. 1C and 6A-6C.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A transistor device comprising:
a base structure; and
a metal oxide layer disposed on the base structure, the metal oxide layer comprising at least one region having a gradient profile with respect to oxygen (O₂) composition.

2. The transistor device of claim 1, wherein the metal oxide layer is disposed on a buffer layer of the base structure.

3. The transistor device of claim 1, wherein the at least one region comprises an interfacial region comprising an interface between the base structure and the metal oxide layer.

4. The transistor device of claim 1, wherein the metal oxide layer corresponds to a channel region of a transistor.

5. The transistor device of claim 4, further comprising:
a gate dielectric disposed on the metal oxide layer; and
a gate conductor disposed on the gate dielectric.

6. The transistor device of claim 5, wherein the at least one region comprises an interfacial region comprising an interface between the gate dielectric and the metal oxide layer.

7. The transistor device of claim 4, wherein the metal oxide layer further corresponds to a pair of source/drain regions.

8. A method comprising:
obtaining a base structure of a transistor device; and
forming, on the base structure using a gas mixture comprising oxygen (O₂), a metal oxide layer comprising at least one region having a gradient profile with respect to O₂ composition.

9. The method of claim 8, wherein the metal oxide layer is formed on a buffer layer of the base structure.

10. The method of claim 8, wherein the at least one region having a gradient profile with respect to O₂ composition comprises an interfacial region comprising an interface between the base structure and the metal oxide layer.

11. The method of claim 10, wherein forming the metal oxide layer comprises:
initiating, at a first time and at a first O₂ flow, a deposition process to form the metal oxide layer;
ramping up, from the first time to a second time, the first O₂ flow to a second O₂ flow to form the interfacial region wherein the second O₂ flow is approximately equal to an inert gas flow; and
forming a bulk region and a second interfacial region of the metal oxide layer.

12. The method of claim 10, wherein forming the metal oxide layer comprises:
initiating, at a first time and at a first O₂ flow, a deposition process to form the metal oxide layer;
maintaining the first O₂ flow for a period of time defined between the first time and a second time;
ramping up, from the second time to a third time, the first O₂ flow to a second O₂ flow to form the interfacial region, wherein the second O₂ flow is approximately equal to an inert gas flow; and
forming a bulk region and a second interfacial region of the metal oxide layer.

13. The method of claim 10, wherein forming the metal oxide layer comprises:
initiating, at a first time and at a first O₂ flow, a deposition process to form the metal oxide layer;
performing an anneal process at a second time to form the interfacial region; and
forming a bulk region and a second interfacial region of the metal oxide layer.

14. The method of claim 8, further comprising forming a gate dielectric on the metal oxide layer, wherein the at least one region having a gradient profile with respect to O₂ composition comprises an interfacial region comprising an interface between the metal oxide layer and the gate dielectric.

15. The method of claim 14, wherein forming the metal oxide layer comprises:
forming a portion of a metal oxide layer using a gas mixture having a first O₂ flow; and
ramping down the first O₂ flow to a second O₂ flow to form the interfacial region.

16. The method of claim 15, wherein the portion of the metal oxide layer comprises a second interfacial region comprising a second interface between the base structure and the second interfacial region, and a bulk region disposed between the interfacial region and the second interfacial region.

17. The method of claim 14, wherein forming the metal oxide layer comprises:
forming a portion of a metal oxide layer using a gas mixture having a first O₂ flow; and
ramping down, from a first time to a second time, the first O₂ flow to a second O₂ flow; and
maintaining the second O₂ flow for a period of time defined between the second time and a third time to form the interfacial region.

18. The method of claim 14, wherein forming the gate dielectric comprises using a deposition process performed at a target temperature to cause a target dissociation of O₂ from the metal oxide layer.

19. The method of claim 18, wherein the deposition process is a chemical vapor deposition (CVD) process.

20. The method of claim 8, wherein the metal oxide layer is formed using a physical vapor deposition (PVD) process.
